(19) United States
(12) Patent Application Publication
(10) Pub. No.: US 2024/0157641 A1
(43) Pub. Date: May 16, 2024

(54) DIRECTED ENERGY BEAM DEFLECTION FIELD MONITOR AND CORRECTOR

(71) Applicant: NIKON CORPORATION, Tokyo (JP)

(72) Inventors: Jacek Kazimierz TYMINSKI, Mountain View, CA (US); Michael Birk BINNARD, Belmont, CA (US)

(73) Assignee: NIKON CORPORATION, Tokyo (JP)

(21) Appl. No.: 18/281,634

(22) PCT Filed: Mar. 4, 2022
(86) PCT No.: PCT/US2022/018981

§ 371 Date: Sep. 12, 2023

Related U.S. Application Data
(60) Provisional application No. 63/160,654, filed on Mar. 12, 2021.

(51) Int. Cl. B29C 64/268; B29C 64/227; H01J 37/22; H01J 37/26; H01J 37/28

(52) U.S. Cl. CPC B29C 64/268; B29C 64/227; H01J 37/222; H01J 37/265; H01J 37/28

(57) ABSTRACT

Directed energy beam deflections are compensated by mapping pixel coordinates of an image of a patterning field to patterning field spatial coordinates. For example, electron beam scanning is compensated by imaging calibration features defined on a reticle to produce a mapping between pixel and physical coordinates. An electron beam is scanned to produce cathodoluminescence at a plurality of scan locations in a patterning field. With the pixel coordinate mapping, an image of the cathodoluminescence is used to determine compensated scan drive values. Other directed energy beam deflections can be similarly compensated.

### CROSS-REFERENCE TO RELATED APPLICATIONS

This application claims the benefit of U.S. Provisional Application 63/160,654, filed Mar. 12, 2021, which is incorporated herein by reference.

### FIELD

The disclosure pertains to manufacturing using an electron beam, laser beam, or other directed-energy beam.

### BACKGROUND

Electron beams can be used in additive manufacturing (AM) or cutting and drilling operations and are well suited for the production of metallic parts. In such systems, metal powders or wires are heated and fused together to form a metallic part layer by layer. Electron beams can be tightly focused and can deliver power suitable for melting metals. In addition, electron beam deflectors can be used to electronically scan an electron beam over a substantial processing area without need for mechanical scanning. Unfortunately, electron beam shape, size, and position tend to be difficult to establish precisely without manual calibration procedures that can be time consuming. Laser-based AM systems exhibit similar problems in providing suitable laser beam positioning. Additional approaches to delivering electron beams, laser beams, or other directed energy beams accurately are needed.

### SUMMARY

Methods of providing compensated deflections to a charged-particle beam (CPB) or a laser-based system comprise, with a camera, obtaining at least one image of a reticle situated at a patterning field in a CPB additive manufacturing (AM) system, the reticle defining a plurality of calibration features. The image of the reticle is processed so that pixel coordinates can be associated with patterning field spatial coordinates. In some examples, pixel coordinates of the calibration features in the image are mapped to patterning field spatial coordinates based on locations in the patterning field and the image. Electron beam deflections (or laser beam deflections) are established in the AM system patterning field based on the mapping. In some examples, the locations of the plurality of calibration features in the patterning field are obtained by translating each of the pattern features to a reference location in the patterning field and recording the translations. In some cases, the reference location is situated on an axis of the camera. In further examples, the processing of the image of the reticle to map pixel coordinates in the at least one image of the reticle to patterning field spatial coordinates is based on predetermined locations of the plurality of calibration features on the reticle. According to representative examples, the camera is situated along an axis that is tilted with respect to an axis of the AM system; typically an optical axis of the CPB optical system, and the at least one image of the reticle exhibits keystone distortion based on the tilt, wherein the processing of the image of the reticle to map pixel coordinates in the at least one image of the reticle to patterning field spatial coordinates includes compensating for the keystone distortion.

In representative embodiments, an electron beam is directed to each of a plurality of scan locations on a target situated in the patterning field by using respective electron beam deflection signals. At least one image of cathodoluminescence (or, in alternate embodiments, plasma emission, or blackbody radiation) from the scan locations in response to the electron beam is obtained and compensated electron beam deflections in the AM system for the patterning field are established based on the mapping of pixel coordinates to spatial coordinates and the at least one image of the cathodoluminescence from the scan locations. In some examples, pixel coordinates of the scan locations in the at least one image are mapped to respective locations in the patterning field, wherein the establishing the electron beam deflections in the AM system for the patterning field is based on the mapping of pixel coordinates to spatial coordinates and the at least one image of the cathodoluminescence from the scan locations. Typically, a workpiece situated in the patterning field is processed by deflecting the electron beam to a plurality of locations using electron beam deflections established by the mapping. The mapping can comprise a database of compensated electron beam deflections and the deflections applied are determined by interpolation of values from the database. The mapping can also comprise a mathematical function that is a fit to the compensated electron beam deflections and the applied deflections are determined by the mathematical function.

Methods of providing compensated deflections to a charged-particle beam (CPB) in an additive manufacturing system comprise, with the CPB, defining a plurality of calibration features on a target situated at a patterning field. With a camera, an image of the plurality of calibration features situated at the patterning field is obtained. The image of the reticle is processed to map pixel coordinates of the calibration features in the image to patterning field spatial coordinates based on locations, which are known a priori, of the calibration features in the patterning field. Electron beam deflections in the AM system patterning field are established based on the mapping. In some alternatives, the locations of the plurality of calibration features in the patterning field are established by translating each of the calibration features to a reference location in the patterning field and recording the translations. Typically, coordinates of the calibration features formed by the electron beam are measured to establish the locations of the plurality of calibration features in the patterning field.

AM apparatus comprise a CPB source and a CPB deflector operable to deflect a CPB from the CPB source to a patterning field. A camera is situated to produce an image of the patterning field and a deflection driver is coupled to the CPB deflector and operable to produce compensated CPB deflections based on an image of a calibration pattern situated in the patterning field obtained with the camera. In some examples, the deflection driver is operable to deflect the CPB to a plurality of scan locations on the target to produce a cathodoluminescence image with the camera, and the compensated CPB deflections are based on the image of a calibration pattern and the cathodoluminescence image of the scan locations. In representative examples, the camera is situated along an axis that is tilted with respect to an axis of the CPB or a perpendicular at the patterning field. A memory can be provided to store nominal deflection drive values associated with the scan locations and/or the associated patterning field coordinates. According to representative embodiments, the deflection driver is operable to map pixel coordinates of the calibration features in the image to patterning field coordinates based on locations of the calibration features in the patterning field. The deflection driver is operable to receive a part specification and produce compensated CPB deflections with the CPB deflector in response to the part specification.

Deflection control systems for a CPB comprise a camera situated to obtain an off-axis image of reticle situated at a working location and defining a plurality of calibration features, and a cathodoluminescence image of cathodoluminescence from a plurality of scan locations. A processor is coupled to the camera to receive the off-axis image of the reticle and the cathodoluminescence of the scan locations and determine compensated deflection values based on the images.

The foregoing and other features, and advantages of the technology will become more apparent from the following detailed description, which proceeds with reference to the accompanying figures.

### BRIEF DESCRIPTION OF THE DRAWINGS

FIG. 1 illustrates a representative additive manufacturing system (AMS) that includes electron beam deflection compensation.

FIG. 2 illustrates a representative method of compensating electron beam scanning in an AMS.

FIGS. 3A-3B illustrate a representative method of compensating electron beam scanning.

FIG. 4 illustrates a representative AMS that includes camera-based electron beam scan compensation.

FIG. 5 illustrates a representative method of compensating beam deflection using calibration markings made with an AMS electron beam.

FIGS. 6A-6B illustrate an AMS that produces beam scan calibration features using an electron beam.

FIG. 7 illustrates a representative computing and control environment for any of the disclosed methods and apparatus.

FIG. 8 illustrates a representative method for additive manufacturing using a scan compensated electron beam.

FIGS. 9A-9C illustrate distortion and misalignment during a printing process.

FIG. 10 illustrates a representative method of calibrating deflections of a printing beam FIG. 11A illustrates a calibration reticle that includes a plurality of reference marks.

FIG. 11B illustrates a deflection field with respect to the reference marks on the calibration reticle.

FIG. 11C illustrates a position of the patterning base with respect to the image of the calibration reticle.

FIG. 11D illustrates a position of the patterning base with respect to the image of the calibration reticle and the deflection field.

FIG. 11E illustrates a feature printed based on alignment of the deflection field with the patterning base.

FIG. 11F illustrates a distorted deflection field with respect to the prior deflection shown in FIG. 11B.

FIG. 11G illustrates patterning base misalignment after printing an M^{th} layer.

FIG. 11H illustrates mapping a deflection field to the distorted and/or misaligned patterning base.

FIG. 11I illustrates a feature printed based on the mapping illustrated in FIG. 11H.

### DETAILED DESCRIPTION

### General Considerations and Terminology

As used in this application and in the claims, the singular forms “a,” “an,” and “the” include the plural forms unless the context clearly dictates otherwise. Additionally, the term “includes” means “comprises.” Further, the term “coupled” does not exclude the presence of intermediate elements between the coupled items.

The systems, apparatus, and methods described herein should not be construed as limiting in any way. Instead, the present disclosure is directed toward all novel and non-obvious features and aspects of the various disclosed embodiments, alone and in various combinations and sub-combinations with one another. The disclosed systems, methods, and apparatus are not limited to any specific aspect or feature or combinations thereof, nor do the disclosed systems, methods, and apparatus require that any one or more specific advantages be present, or problems be solved. Any theories of operation are to facilitate explanation, but the disclosed systems, methods, and apparatus are not limited to such theories of operation.

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed systems, methods, and apparatus can be used in conjunction with other systems, methods, and apparatus. Additionally, the description sometimes uses terms like “produce” and “provide” to describe the disclosed methods. These terms are high-level abstractions of the actual operations that are performed. The actual operations that correspond to these terms will vary depending on the particular implementation and are readily discernible by one of ordinary skill in the art.

In some examples, values, procedures, or apparatus' are referred to as “lowest”, “best”, “minimum,” or the like. It will be appreciated that such descriptions are intended to indicate that a selection among many used functional alternatives can be made, and such selections need not be better, smaller, or otherwise preferable to other selections.

Examples are described with reference to directions indicated as “above,” “below,” “upper,” “lower,” and the like. These terms are used for convenient description, but do not imply any particular spatial orientation.

The examples are generally described with reference to electron beams, but any directed energy beam such as a charged particle beam (CPB) or laser beam can be used. While specific examples are described individually for clarity, any of these examples can be combined with any other examples. In the examples, a position of a target with respect to a CPB is measured and in some cases, the position of the target or a position of the CPB are adjusted based on the measurement. Target position is generally adjusted with a motion controlled stage device, a piezo-actuator, or any other positioner. CPB position is typically adjusted with an electrostatic or electromagnetic deflector by application of suitable voltage or current. In most practical examples, deflectors are controlled using control voltages that are applied to deflector drive electronics which produce the intended voltages or currents provided to the CPB deflectors using one or more amplifiers or buffer circuits. As used herein, the terms “deflector drive value,” “drive values” or similar terms are used to refer to currents or voltages used to control CPB deflections. The term “deflection” refers to linear or angular deflections of a CPB. In the examples, apertures are generally illustrated as circular and are defined in a corresponding aperture plate. However, apertures can be slits, edges, polygons, ovals, or other shapes as convenient. While such apertures can be defined in dedicated aperture plates, other elements in a CPB column can be used to define these apertures as well. For convenience, CPB propagation is generally described as being along a Z-axis and apertures are situated in an XY-plane of a coordinate system. In the examples, suitable deflectors for CPBs are used. In examples using a laser beam, electro-optic, acousto-optic, galvanometer, rotatable reflectors, polygon beam scanners, or other optical scanners can be used.

As used herein, “image” refers to a visual display suitable for viewing by an operator, technician, or other person or to data associated with such visual displays. Images thus include data files such as jpg, tiff, bmp, or files in other formats. In some examples below, visual images are provided for purposes of explanation, but digital images are used in computations.

For convenient explanation, some features or method steps are shown separately, but some or all features or steps can be performed with a common apparatus, if desired. In the examples, nominal defection drive values produce deflections of a CPB to locations that can be different from the intended locations. The examples below are directed to approaches that permit these nominal drive values to be compensated to more closely align the CPB with an intended CPB target location.

Embodiments are described with reference to providing compensated or calibrated beam drive values with respect to a patterning field at which AM processing is anticipated. As used herein, patterning field also refers to a reference field which can be used for scan compensation. Coordinate mappings from pixel to physical coordinates are used in the examples, but such mappings also include mappings from physical to pixel coordinates. Cutting, drilling, or other material removal operations can also use the disclosed methods and apparatus, and the examples are generally described with reference to additive manufacturing for purposes of illustration.

The examples are generally described with reference to targets or substrates situated on a multi-axis translational stage but rotary stages can be used and beam deflections for use with rotational stages such as a turntable or other rotational stages, or combined rotational/translational stages. Beam deflection values are illustrated for convenience in rectilinear (xyz) coordinates, but other coordinated such as polar (r, θ) coordinates can be used. Polar coordinates may be more convenient for systems that include a rotational stage.

### Representative Electron Beam Additive Manufacturing System

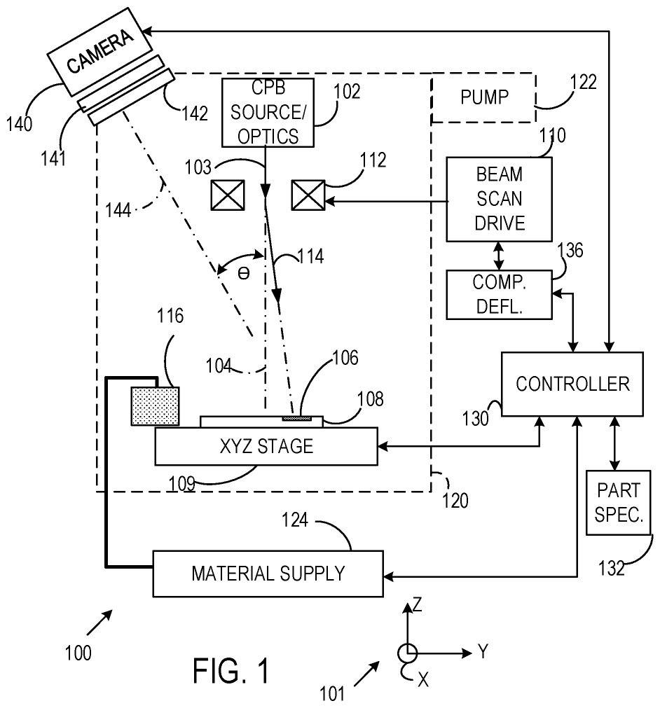

Referring to FIG. 1, a representative additive manufacturing system (AMS) 100 includes a charged particle beam (CPB) source 102 and associated optics situated to direct an electron beam 103 along an axis 104 toward a target area 106 on a substrate 108. A representative XYZ coordinate system 101 is shown for convenient description. The substrate 108 is retained by an XYZ stage 109 although rotational stages can be used as well. Substrates or targets situated on an XYZ stage can be moved in and out of a beam deflection field or situated within the beam deflection field. Similarly, in a system using a rotational stage, targets or substrates can be moved by rotation of a turntable in and out of the beam deflection field, but typically such systems are configured so that substrates or targets are situated with the beam deflection field. A beam scan driver 110 is coupled to a beam deflector 112, typically implemented as a magnetic octupole deflector but in some cases can be a quadrupole, sextupole. or some other multipole deflector, or an electrostatic deflector, to scan the electron beam 103 to produce a deflected beam 114 that is used for processing at selected areas of the substrate 108. For convenience, an area accessible for additive manufacturing is referred to herein as a patterning field. Target areas used for beam deflection correction and compensation can be situated within the patterning field, at a perimeter of the patterning field such as at a corner of the patterning field, or can be moved into and out of the beam deflection field with the XYZ stage 109 (or with a rotational stage).

A material reservoir 116 is situated proximate the substrate 108 and provides material for layer by layer additive manufacturing. The substrate 108, the material reservoir 116, the beam deflector 112, and the CPB source 102 are situated in a vacuum enclosure 120 that is evacuated with one or more pumps 122. In alternative embodiments some of these components (e.g., the beam deflector 112 or portions of the XYZ stage 109) may be located outside the vacuum enclosure 120. An additional material reservoir 124 is situated exterior to the vacuum enclosure 120 can be coupled to the material reservoir 116 to deliver additional material into the vacuum enclosure 120 for manufacturing, although in some cases, vacuum in the vacuum enclosure 120 must be restored after additional material is supplied. In some cases, material is supplied as wire or powder of materials such as titanium, stainless steel, or other alloys. During processing, material from the material reservoir 116 is added as the CPB source 102 is used to melt the target area 106 on the substrate 108.

A controller 130 is coupled to memory 132 or to a remote network to receive a part specification such as a computer-aided design data that defines a part to be manufactured. The controller 130 is coupled to a memory 136 that stores processor-executable instructions, scan data values, or other data so that compensated beam scan values can be provided to the beam scan driver 110. A camera 140 is situated to image the patterning field through a vacuum window 142 along an axis 144 that is tilted at an angle θ (generally greater than 5, 10, 15, 20, 25, 30, 35, 40, 45, or 50 degrees) with respect to the substrate 108. The camera 140 is coupled to the controller 130 to provide an image of a reticle having a defined reference pattern placed as substrate 108. The camera 140 can further provide an image of cathodoluminescence, plasma emission, or blackbody radiation in response to irradiation of locations at which the deflected beam 114 intersects the substrate 108 in response to a plurality of nominal beam deflection drive values stored in memory or supplied over a network. Wavelengths used for imaging by the camera 140 typically are in a visible range (about 400 nm to 700 nm), a near infrared (about 700 nm to 2500 nm), a near ultraviolet range (about 300 nm to 400 nm), or in a combination of these or other ranges. When a laser beam is used as the directed energy beam, the wavelength of the laser beam may be different from the wavelength range that is used for imaging by the camera 140. A dichroic filter 141 can be situated to selectively block optical radiation at the laser wavelength and transmit (or reflect) optical radiation used for imaging to the camera 140. The imaged locations can be situated at a perimeter of a patterning field, within the patterning field, or translated or rotated into an out of the beam deflection area. Comparison of these images permits determination of compensated deflection values as discussed in detail below. The image of the patterned reticle permits a distorted image of the patterning field (which typically includes at least keystone distortion as shown) to be corrected so that image coordinates (“pixel coordinates”) can be mapped to physical coordinates in the patterning field. Once the camera distortions are suitably mapped, such mapping is generally stable and need not be redone. By producing cathodoluminescence images periodically, compensated deflection values can be re-determined as necessary to correct for change over time of the CPB source 102 or the beam deflector 112 with minimal operator intervention. Calibration data based on a reticle image can be reused once these data are acquired and repeated calibration is not generally necessary in processing multiple substrates.

### Compensated Electron Beam Deflections

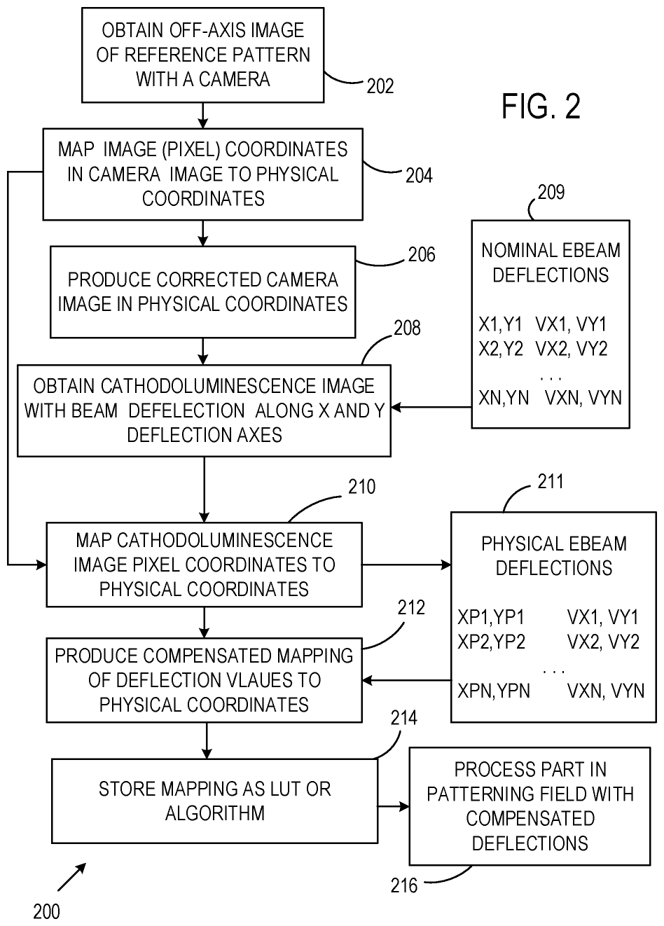

Referring to FIG. 2, a method 200 of processing images to map pixel coordinates to spatial coordinates includes obtaining an image of a reference pattern defined on a reticle with a camera at 202. While a reticle is convenient, reference locations defined on any suitable substrate can be used such as a previously manufactured part or any target for which coordinate locations are known or can be determined. The reticle is situated at a patterning field in an AM system and the camera image is typically an off-axis image that exhibits appreciable distortion. In some cases, the reticle is placed by an operator or with a robot arm. At 204, pixel coordinates of calibration features in the camera image of the reference pattern are mapped to physical coordinates in the patterning field. At 206, a corrected image of the reticle can be produced and stored, and, if desired, displayed for visual inspection to confirm the pixel mapping. At 208, one or more cathodoluminescence images of a target situated at the patterning field are produced by continuous, stepwise, or other scanning by the electron beam (in a laser-based system, the laser beam directly illuminates the target reticle) with a set of nominal beam deflection values (VX1, VY1), . . . , (VXI, VYJ) and nominal coordinates (X1, Y1) . . . (XI, YJ), wherein I, J are positive integers. In other words, (XI, YJ) are the desired target locations and (VXI, VYJ) are the deflection commands that are meant to deflect the beam to intersect the target at (XI, YJ). These can be obtained from a database stored in a memory as illustrated at 209, computed as needed, or provided in user input. In most examples, deflections are two dimensional (i.e., in an XY plane at the patterning field), but one, two, or three-dimensional nominal scan values can be compensated.

The cathodoluminescence images are represented in pixel coordinates as obtained from the camera, and at 210, pixel coordinates of the cathodoluminescence images are mapped to physical coordinates in the patterning field and can be stored in a database in memory as illustrated at 211. With this mapping, actual (physical) deflections (XPI, YPJ) produced with drive values (VXI, VYJ) are available. At 212, a compensated mapping of nominal deflection commands to actual (physical) coordinates is produced as a look-up table (LUT) or fitted algorithm and stored at 214. In some cases, the mapping is based on a linear, polynomial, or other fit or using, for example, Principal Component Analysis (PCA). With the compensated mapping, AM processing can be performed as illustrated at 216. In other words, the mapping 212 specifies the compensated deflection command (VPXI, VPYJ) that will produce deflection to a desired target position (XI, YJ).

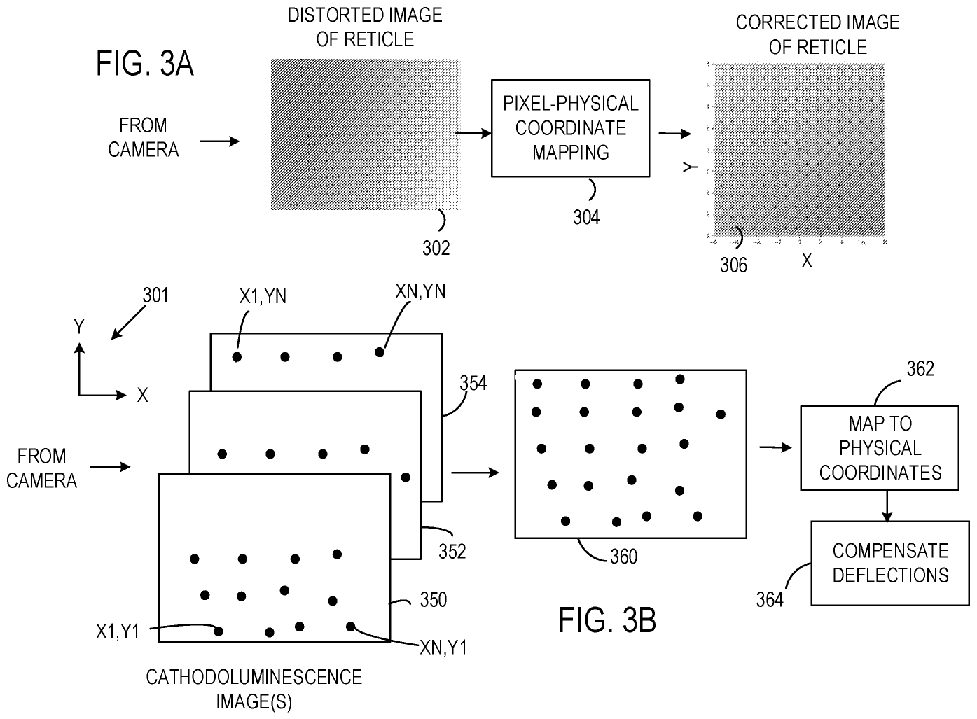

In some examples, the patterning field cannot be easily fit into a single image and multiple images are acquired of one or both of the reticle and the target used in a cathodoluminescence image. In some examples, an origin of coordinates used to describe pattern features on the reticle can be situated with respect to one or more alignment features so that pattern feature locations can be specified. In addition, the reticle can be situated for removal by an operator or a robot, and use of one or more reticle alignment features can permit accurate repositioning when the reticle is returned for calibration. Use of a combined cathodoluminescence image is illustrated in FIGS. 3A-3B with reference to a coordinate system 301. In FIG. 3A, a distorted image 302 of a reticle is received and pixel coordinates are mapped to physical coordinates at 304 using known physical coordinates or distances between calibration features in the reticle. A corrected (compensated) image 306 is produced and can be displayed. This pixel-to-physical mapping is then used to compensate beam deflections as shown in FIG. 3B. In this example, three cathodoluminescence images 350, 352, 354 are required to cover the patterning field. Deflected beam spots associated with nominal coordinates (XI,YJ) are shown for an example with I=J=4. The beam spots may be combined in a combined image 360 and each of the beam spots is mapped from pixel coordinates to physical coordinates at 362. Beam spots need not be combined in a single image and associated mappings can be done using multiple cathodoluminescence images. As noted above, images need not be displayed, but can be, particularly so that an operator can confirm mapping. At 364, a compensated deflection mapping is produced by associating deflection values with physical locations and generating a calibrated look-up table or algorithmic mapping.

### Electron Beam AM with Compensated Deflections

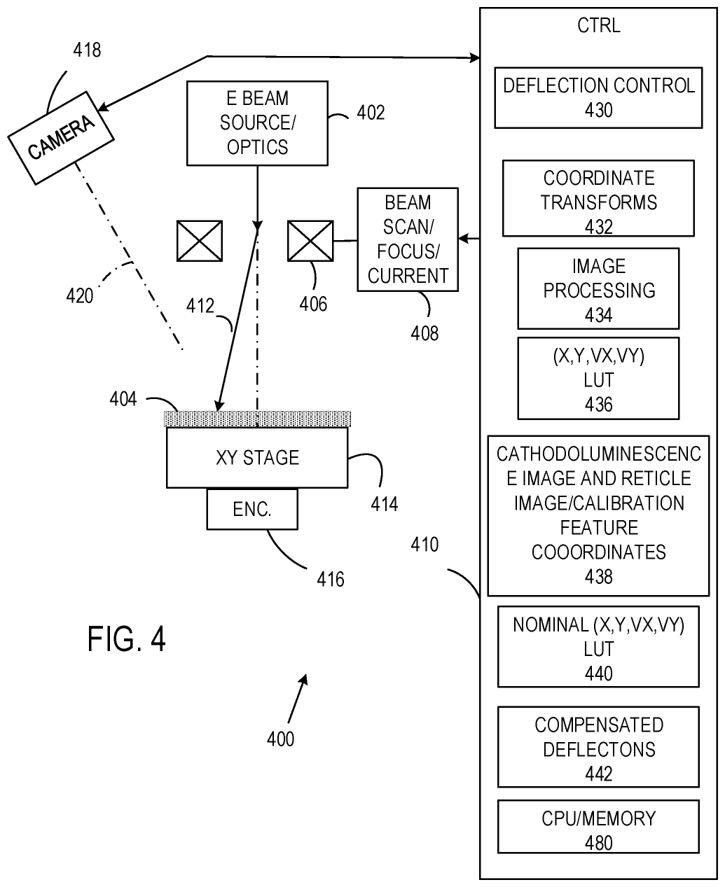

Referring to FIG. 4, a representative electron beam system 400 includes an electron beam source/electron optics 402 that directs an electron beam to a substrate 404 situated at a patterning field. A beam deflector 406 is coupled to deflection/focus control circuitry408 to provide beam deflections in response to control signals or processor-executable instructions provided by a system controller 410 and produce a deflected beam 412. The substrate 404 can be secured to an XY stage 414 which is coupled to an encoder 416 that can also be coupled to the system controller 410 to adjust and record positioning of the substrate 404. A camera 418 is situated on an axis 420 that is tilted with respect to a perpendicular to the substrate 404. The camera 418 can provide cathodoluminescence, plasma emission, or blackbody radiation images to the system controller 410 for use in deflection compensation and coordinate mappings.

The system controller 410 can include a beam deflection controller 430, memory portions 432, 434, 436 that that store processor-executable instructions for coordinate transforms, image processing, a deflection look up table storing values (VPX, VPY) associated with a particular location (XP, YP), and beam focus control, respectively. The system controller 410 also includes one or more processors and additional memory as shown at 480. In addition, the system controller 410 can include a memory portion 438 storing a reticle image and a cathodoluminescence image for additional calibration, a memory portion 440 storing nominal deflection data, and a memory portion 442 storing data and processor-executable instructions for generating compensated deflection values to be supplied to the beam scanner 408.

### Beam Alignment with Beam Generated Calibration Features

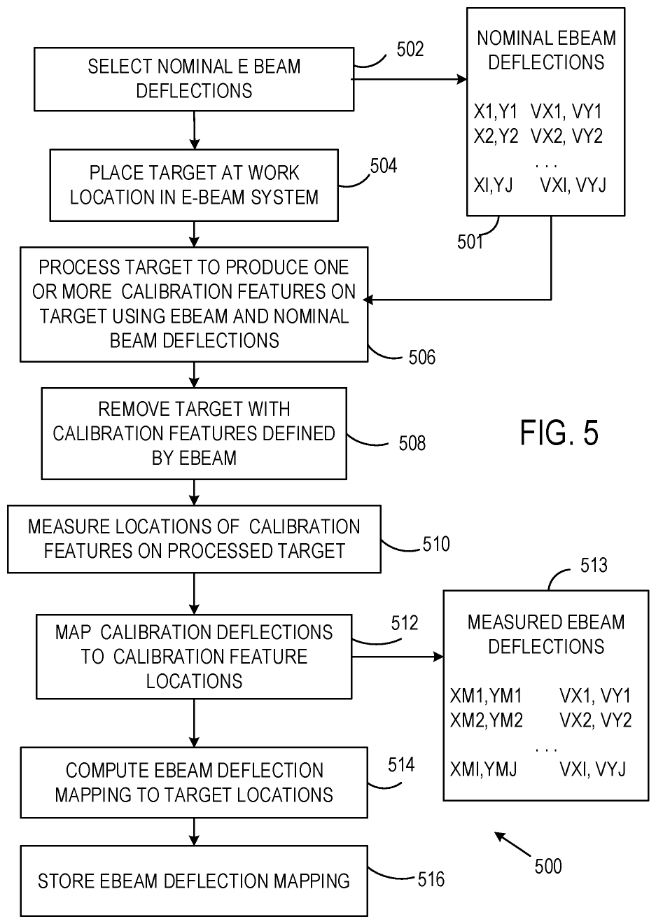

Referring to FIG. 5 a method 500 includes obtaining selected a set 501 of nominal beam deflections (XI,YJ) and associated deflection values (VXI, VYJ) at 502. At 504, a target is situated at a patterning field and at 506, the target is exposed to the electron beam with the set of deflection values. The exposures are configured to generate calibration features on the target such as burn marks, pits, melted and re-solidified areas, or other markings. At 508, the marked target with calibration features produced by the electron beam is removed from an electron beam system so that calibration feature coordinates can be measured at 510. In some examples, the marked target can be measured in the electron beam system by translating or rotating the marked target with one or more stages to one or more reference locations or orientations and recording the translation and/or rotation values. Alternatively, pixel coordinates in a camera image can be used with previously determined mapping of pixel coordinates to physical coordinates. At 512, the nominal deflections are mapped to measured deflections (XM1, YM1), . . . (XMI, YMJ), wherein I, J are positive integers and can be stored at 513. At 514 a mapping of deflection values to physical coordinates is produced and stored at 516. In the approach of FIG. 5, a reticle can be used for image distortion correction but is not required. If a camera is used, it can be calibrated to establish pixel to physical coordinate mappings or used uncalibrated to verify that a mark on the target is positioned at a reference location.

### AM System with Beam Generated Calibration

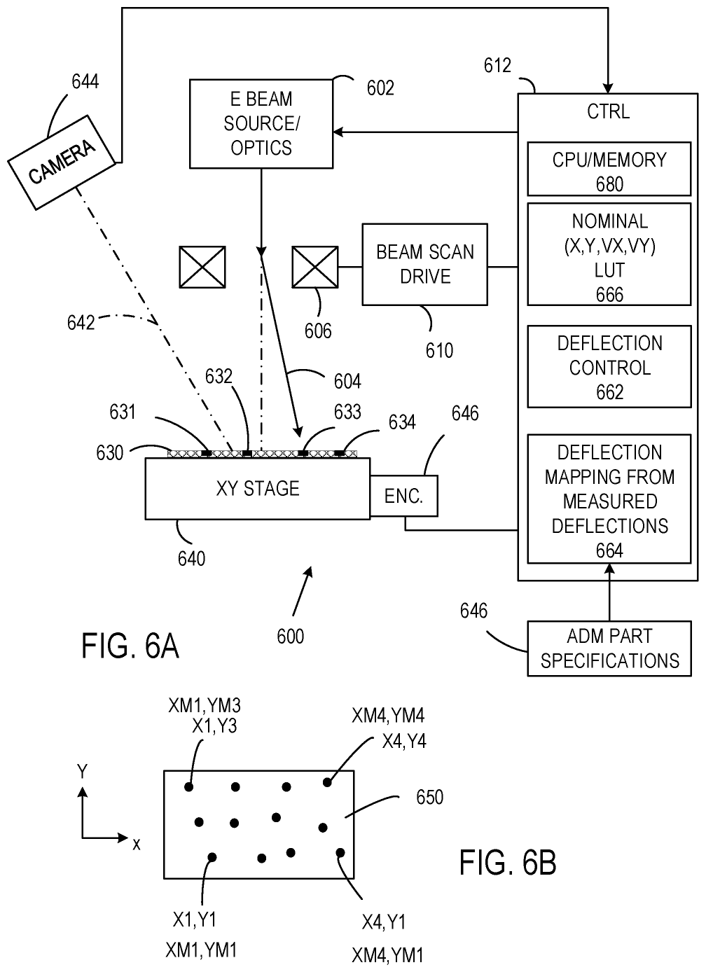

Referring to FIG. 6A, an electron beam AM system 600 includes a beam source 602 that produces a beam 604 that can be scanned with a beam scanner 606 in response to beam scan values (signals) applied by a beam scan drive 610. A control system 612 is coupled to the beam scan drive 610 and scans the electron beam to produce a plurality of calibration marks such as representative pits 631-634 in a substrate 630. Each of the representative pits 631-634 is associated with respective drive values and nominal coordinates. A substrate stage 640 is operable to move each of the pits to a reference location such as a location along an axis 642 of a camera 644, and translations associated with the movement are captured with one or more encoders 646 and the values coupled to the control system 612. Physical coordinates of the pits are available along with associated deflection drive values. These coordinates can be used to establish compensated deflection values as discussed above. Alternatively, if a pixel coordinate to physical coordinate mapping associated with images produced with the camera 644 is available, pit coordinates can be processed in the same manner as cathodoluminescent spot coordinates. A camera is not required to establish translation of the pits to reference locations, and other detection systems can be used. For example, in a system that does not include camera 644, the substrate 630 can be removed from the system and measured by external tools.

The control system 612 can include memory portions 662, 664, 666 storing processor-executable instructions and data for deflection control, deflection mapping/calibration based on the measured deflections, and a lookup table of nominal deflections, respectively. The control system 612 also includes CPU/memory 680 and is operable to recite additive manufacturing part specifications 682 for use in controlling exposures to the electron beam.

FIG. 6B illustrates representative pits situated at various nominal coordinates (XI,YJ) and measured (physical) coordinates (XMI, YMJ) on a target 650. In this example, a 3 by 4 array of pits is produced (I=1, 2, 3, 4 and J=1, 2, 3), and the pits may or may not be uniformly spaced.

### Representative Control and Calculation Environment

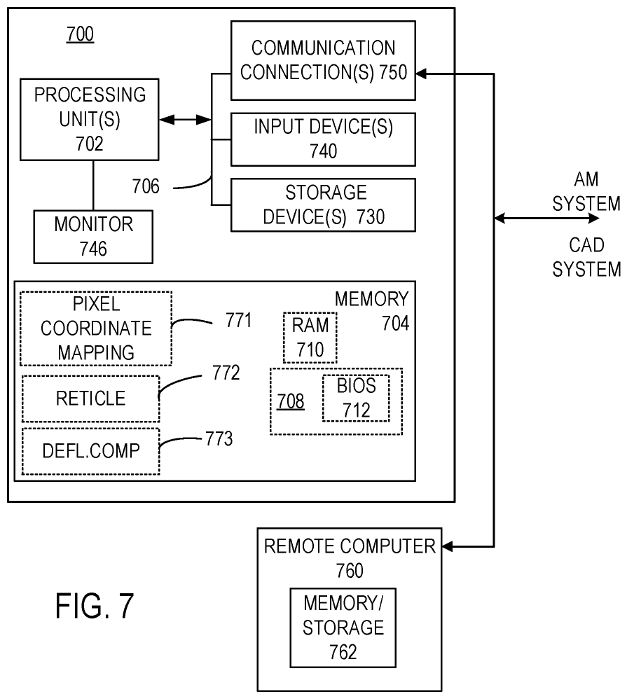

FIG. 7 and the following discussion are intended to provide a brief, general description of an exemplary computing environment in which the disclosed technology may be implemented. Although not required, the disclosed technology is described in the general context of computer-executable instructions, such as program modules, being executed by a personal computer (PC). Generally, program modules include routines, programs, objects, components, data structures, etc., that perform particular tasks or implement particular abstract data types. Moreover, the disclosed technology may be implemented with other computer system configurations, including hand-held devices, multiprocessor systems, microprocessor-based or programmable consumer electronics, network PCs, minicomputers, mainframe computers, application specific integrated circuits (ASICs), field-programmable gate arrays (FPGAs), programmable logic devices (PLDs), systems on a chip (SOCs), and the like. The disclosed technology may also be practiced in distributed computing environments where tasks are performed by remote processing devices that are linked through a communications network. In a distributed computing environment, program modules may be located in both local and remote memory storage devices.

With reference to FIG. 7, an exemplary system for implementing the disclosed technology includes a computing device in the form of an exemplary conventional PC 700, including one or more processing units 702, a system memory 704, and a system bus 706 that couples various system components including the system memory 704 to the one or more processing units 702. The system bus 706 may be any of several types of bus structures including a memory bus or memory controller, a peripheral bus, and a local bus using any of a variety of bus architectures. The exemplary system memory 704 includes read only memory (ROM) 708 and random-access memory (RAM) 710. A basic input/output system (BIOS) 712, containing the basic routines that help with the transfer of information between elements within the PC 700, is stored in ROM 708. The memory 704 also contains portions 771-773 that include computer-executable instructions and data for pixel to physical coordinate mapping, calibration feature coordinates, and generating compensated deflection values, respectively.

The exemplary PC 700 further includes one or more storage devices 730 such as a hard disk drive for reading from and writing to a hard disk, a magnetic disk drive for reading from or writing to a removable magnetic disk, and an optical disk drive for reading from or writing to a removable optical disk (such as a CD-ROM or other optical media). Such storage devices can be connected to the system bus 706 by a hard disk drive interface, a magnetic disk drive interface, and an optical drive interface, respectively. The drives and their associated computer-readable media provide nonvolatile storage of computer-readable instructions, data structures, program modules, and other data for the PC 700. Other types of computer-readable media which can store data that is accessible by a PC, such as magnetic cassettes, flash memory cards, digital video disks, CDs, DVDs, RAMs, ROMs, and the like, may also be used in the exemplary operating environment.

A number of program modules may be stored in the storage devices 730 including an operating system, one or more application programs, other program modules, and program data. A user may enter commands and information into the PC 700 through one or more input devices 740 such as a keyboard and a pointing device such as a mouse. Other input devices may include a digital camera, microphone, joystick, game pad, satellite dish, scanner, or the like. These and other input devices are often connected to the one or more processing units 702 through a serial port interface that is coupled to the system bus 706 but may be connected by other interfaces such as a parallel port, game port, or universal serial bus (USB). A monitor 746 or other type of display device is also connected to the system bus 706 via an interface, such as a video adapter. Other peripheral output devices, such as speakers and printers (not shown), may be included.

The PC 700 may operate in a networked environment using logical connections to one or more remote computers, such as a remote computer 760. In some examples, one or more network or communication connections 750 are included. The remote computer 760 may be another PC, a server, a router, a network PC, or a peer device or other common network node, and typically includes many or all of the elements described above relative to the PC 700, although only a memory storage device 762 has been illustrated in FIG. 7. The personal computer 700 and/or the remote computer 760 can be connected to a logical a local area network (LAN) and a wide area network (WAN). Such networking environments are commonplace in offices, enterprise-wide computer networks, intranets, and the Internet.

When used in a LAN networking environment, the PC 700 is connected to the LAN through a network interface. When used in a WAN networking environment, the PC 700 typically includes a modem or other means for establishing communications over the WAN, such as the Internet. In a networked environment, program modules depicted relative to the personal computer 700, or portions thereof, may be stored in the remote memory storage device or other locations on the LAN or WAN. The network connections shown are exemplary, and other means of establishing a communications link between the computers may be used.

### Representative Manufacturing Methods

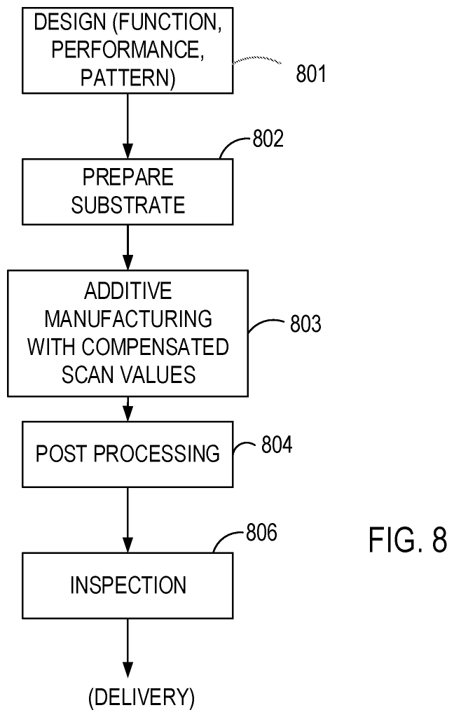

Referring to FIG. 8, a representative method 800 includes selecting or producing a suitable part design at 801 and preparing a substrate at 802. At 803, additive manufacturing is used to fabricate a part according to the design using compensated electron beam deflections. Based on part specifications, nominal beam deflection values are adjusted by the methods and apparatus described above and the resulting compensated deflection commands are used as the compensated scan values. At 804, the manufactured part is post processed as needed such as, for example, to polish or smooth surface or remove excess material added by the manufacturing process. At 806, the part is inspected prior to delivery.

### Representative Method of Printing with Calibration

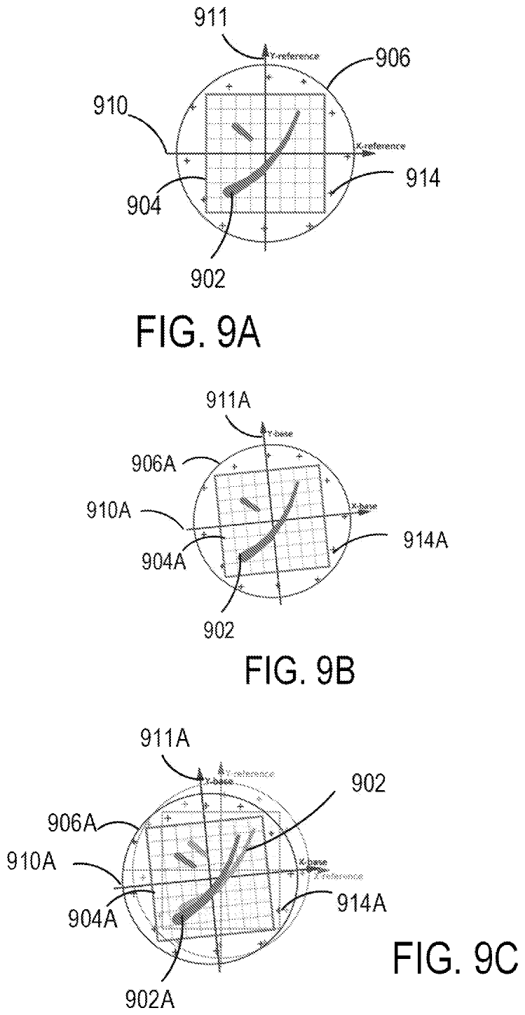

As shown in FIGS. 9A-9C, distortion and misalignment can degrade multilayer printing processes. Typical effects are caused by power loads that alter beam deflections or external electromagnetic fields that alter beam deflections, mechanical imperfections of drive mechanisms used to move a patterning base, and thermal distortion of the patterning base in response to heat flow from a melt pool associated with the printing process. As used below, “patterning field” refers generally to an area in which features can be printed and “printing beam” refers to any directed energy beam suitable for AM. FIG. 9A illustrates a correctly printed feature 902 in a patterning field 904 that is situated with respect to a patterning base 906 which serves as a platform for printing. As an example, the printed feature 902 is shown as a Katakana “n.” In FIG. 9A, the position of features in the patterning field 904 such as the printed feature 902 can be described using coordinates defined with respect to an X-reference axis 910 a and a Y-reference axis 911. The patterning base 906 can include a plurality of reference alignment marks such as the representative alignment mark 914. For purposes of explanation, the arrangement and alignment of the patterning field 904 and the patterning base 906 can be referred to generally as a reference alignment in which the X-reference axis 910 and the Y-reference axis 911 can be used to specify print location. In FIG. 9B, the patterning base 906 is distorted and/or misaligned (a rotation is shown) to become a distorted patterning base 906A with a distorted (rotated) patterning field 904A with shifted alignment marks such as shifted alignment mark 914A. For purposes of explanation, the desired arrangement and alignment of the shifted patterning field 904A and the distorted patterning base 906A are used to print additional features/layers using coordinates specified by an X-base axis 910A and a Y-base axis 911A. FIG. 9C illustrates printing of a pattern feature 902A using coordinates referred to the X-base axis 910A and the Y-base axis 911A and showing the X-reference axis 910 and the Y-reference axis 911. As apparent, the printed features 902, 902A do not align.

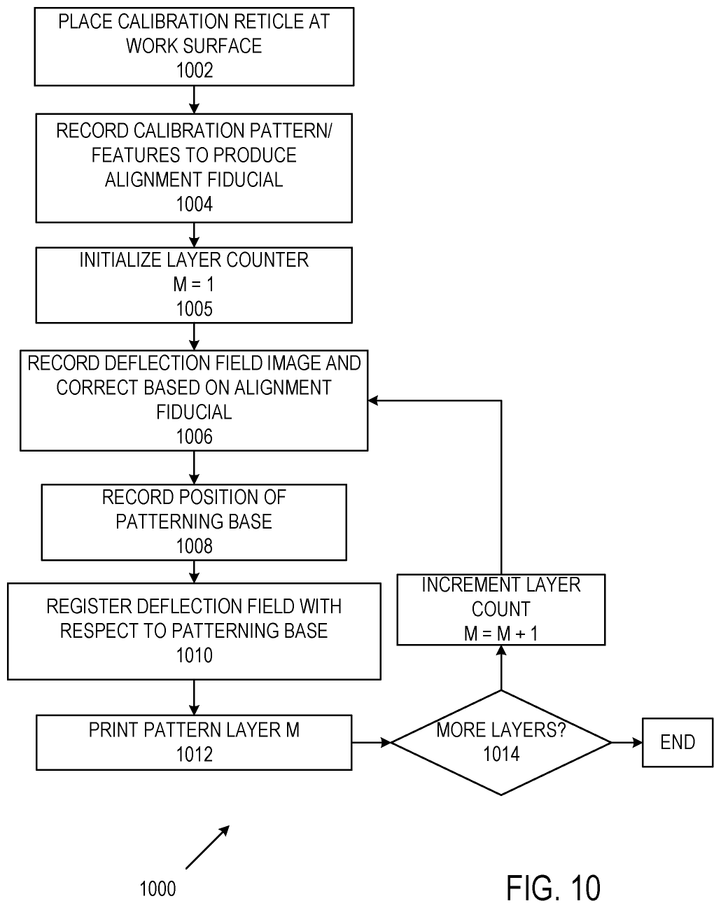

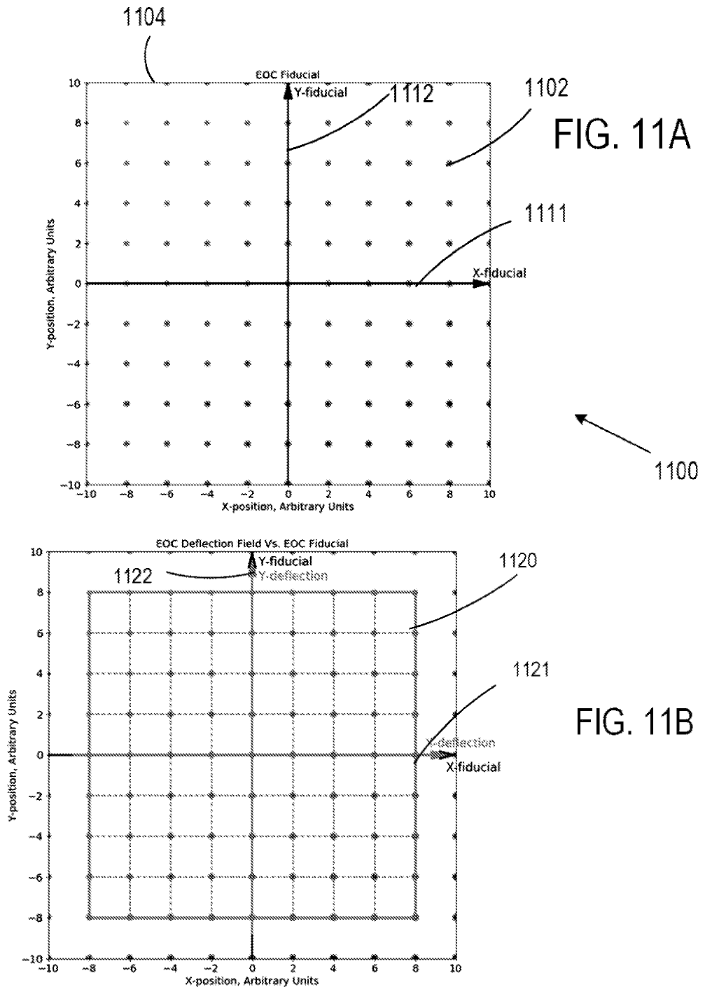

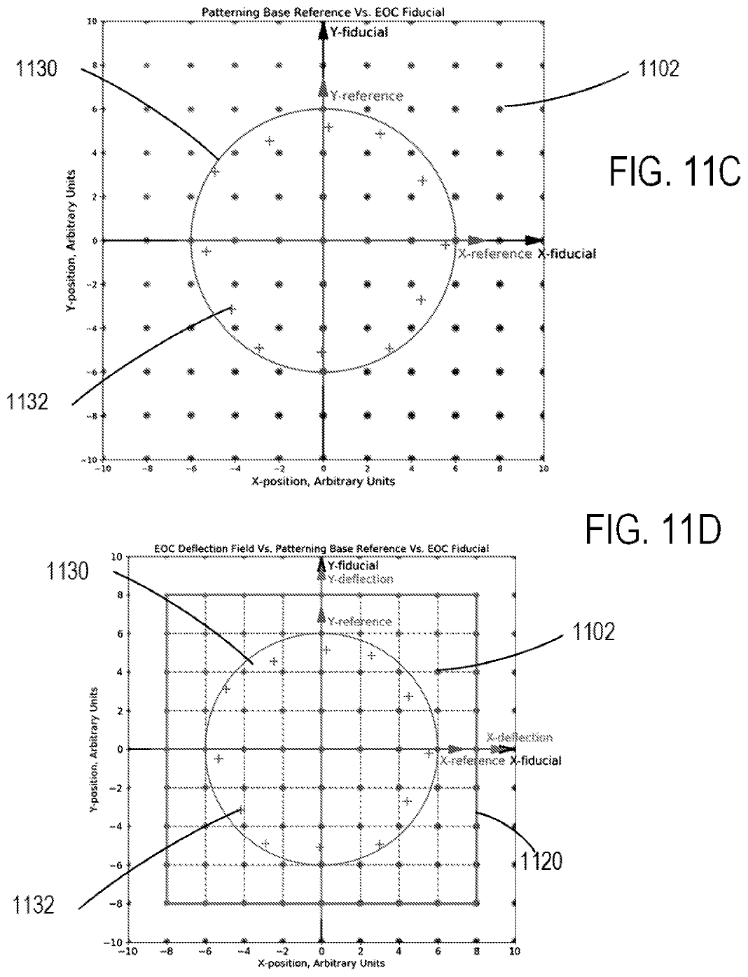

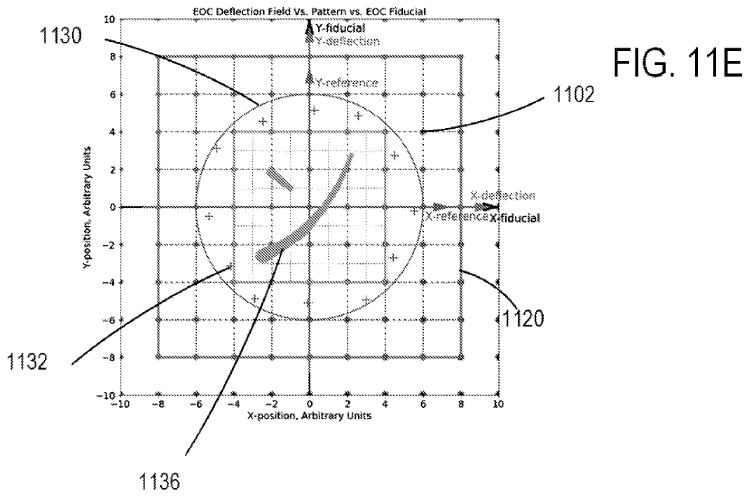

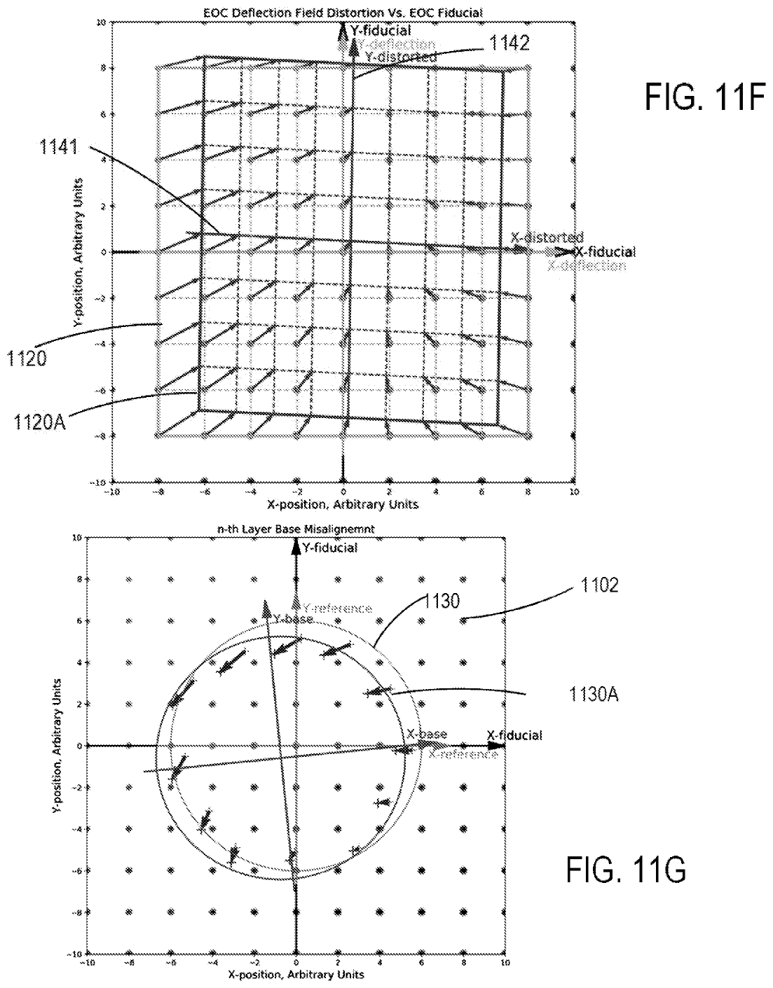

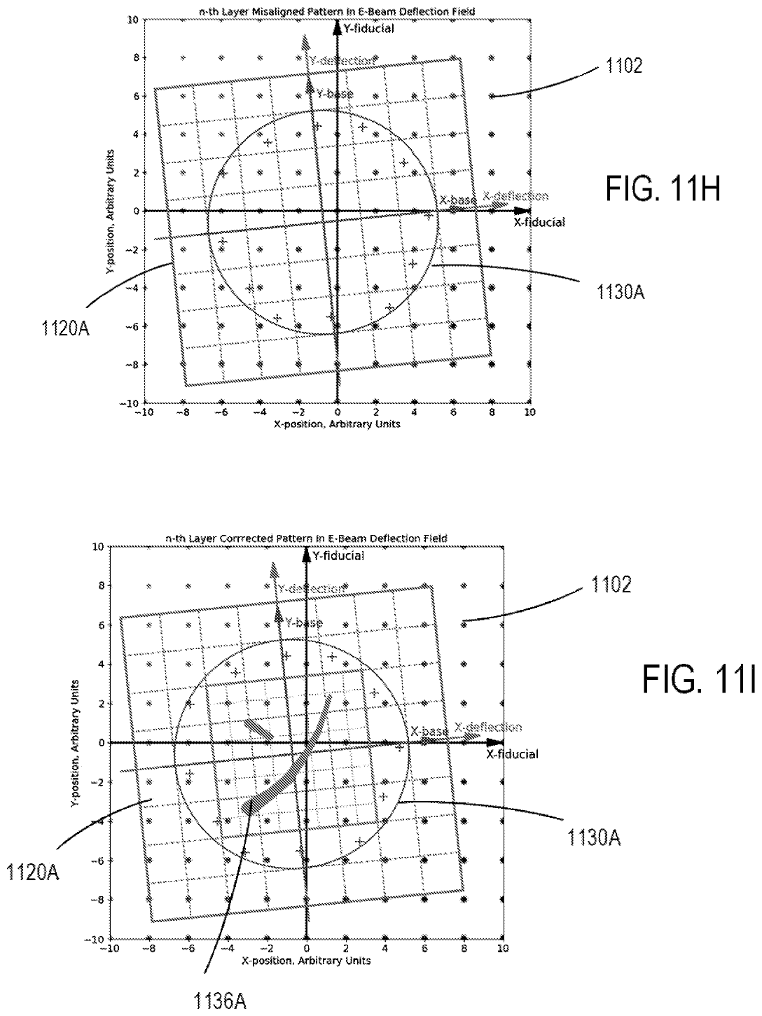

The printed distortion shown in FIG. 9C can be addressed using a method 1000 illustrated in FIG. 10 with orientations illustrated in FIGS. 10A-10I. At 1002, a calibration reticle such as a calibration reticle 1100 shown in FIG. 11A is situated in a patterning field. The calibration reticle 1100 includes a plurality of reference marks such as representative reference mark 1102 situated in area 1104 that corresponds to or permits establishing locations with reference to a patterning field. The reference marks are shown as a rectangular array that is aligned with an X-fiducial axis 1111 and a Y-fiducial axis 1112 but other regular or random arrangements and spacings of reference features can be used. The area 1104 containing reference marks need not cover the entire patterning field and can be exterior to the patterning field but it is typically preferable to provide reference marks throughout the patterning field. The calibration reticle 1100 can include reference marks made in a metallic layer on a transparent substrate such as glass or fused silica, but patterns formed in other ways can also be used.

At 1004. the arrangement of reference marks in the patterning field can be recorded and stored, producing an alignment fiducial which can be used to establish beam deflections, typically based on an image of the calibration reticle 1100 obtained with a camera. Reference mark locations on the calibration reticle 1100 are established in, for example, X-fiducial and Y-fiducial coordinates with respect to the X-fiducial axis 1111 and the Y-fiducial axis 1112, but can be specified with other coordinates. The image of the calibration field permits mapping of camera coordinates to coordinates in the patterning field; image distortion in camera images can be compensated based on locations of reference marks on the calibration reticles.

At 1005, layer counter M is initialized and a printing pattern associated with the initial value of M is selected. At 1006, a printing beam (for example, a CPB such as an electron beam or a laser beam) is scanned over a deflection field in the patterning field and printing beam deflection values are corrected based on locations with respect to the alignment fiducial. As shown in FIG. 11B, the printing beam scan can correspond to a grid 1120 and the printing beam can be deflected along an X-deflection axis 1121 and a Y-defection axis 1122 that are aligned with respect to the to the alignment fiducial. The printing beam scan need not be initially aligned but can be corrected as needed to produce the aligned grid 1120. The printing beam scan can be recorded based on cathodoluminescence, plasma emission, blackbody radiation or by imaging with a camera, or one or more apertures can be situated in the patterning field and transmission of the printing beam measured at various aperture locations in the patterning field. At 1008, a position of a patterning base is recorded. FIG. 11C shows an outline 1130 of the patterning base superposed on the pattern defined by the calibration reticle 1100. The patterning base can include a plurality of base reference features such as the base reference feature 1132. An image of the patterning base can be recorded, and at 1010, the deflection field and the patterning base are aligned with respect to the alignment fiducial as shown in FIG. 11D. With the deflection field and the patterning base aligned, at 1012, an M^{th} layer 1136 is printed as shown in FIG. 11E.

As noted above, printing beam deflection and patterning base position and distortion tend to vary during printing, and if additional layers are to be printed as determined 1014, the layer counter M can be incremented and the procedure described above can be used to confirm or re-establish alignment. For example, referring to FIG. 11F, deflection field 1120A (associated with an X-distorted axis 1141 and a Y-distorted axis 1142) that is distorted or otherwise changed from the original deflection field 1120 of FIG. 11B is measured and corrected at 1006. A position of the patterning base is recorded again at 1008. For example, as shown in FIG. 11G, a misaligned patterning base has an outline 1130A that is offset and rotated from the outline 1130 of the patterning base used in printing the previous layer. FIG. 11H illustrates mapping a deflection field to the distorted or misaligned patterning base 1130A and FIG. 11I illustrates a feature printed feature 1136A printed based on the mapping illustrated in FIG. 11H.

Using the measurements described about, printing beam deflections can be determined to compensate changes such as translations, rotations, or distortions of one or more or both of the deflection field and the patterning base. Typically, the deflection field and the patterning base are located with respect to each other by mapping to the alignment fiducial. Thus, for each layer, deflections needed for printing a desired structure can be referenced to the alignment fiducial (specified by the calibration reticle) and offsets, rotations, and deformations of the deflection field and patterning base compensated so that corrected deflections are applied to the printing beam.

The positioning of the calibration reticle and reference features with respect to the patterning field (or other deflection field of the patterning beam) is generally not critical, but it is usually preferable that the calibration reticle cover an anticipated area of the patterning field that is to be used in a particular printing process. While the deflection field and/or the patterning base can be remapped after printing each layer, remapping can be provided after a predetermined number of layers such as 2, 5, 10, 50, 100, or more depending on stability of the patterning base with respect to the deflection field and a desired accuracy. In some examples, distortions or other changes are measured, and remapping carried out only if indicated by measured values.

### Representative Examples

Example 1 is a method of providing compensated deflections to a directed energy beam, including: directing an energy beam to a target situated in a patterning field to each of a plurality of scan locations using respective beam deflection signals; obtaining at least one image of cathodoluminescence, plasma emission, blackbody radiation, or surface damage from the scan locations in response to the directed energy beam; and establishing compensated beam deflections for the patterning field based on a mapping of pixel coordinates of the at least one image of the cathodoluminescence, plasma emission, blackbody radiation, or surface damage from the scan locations to spatial coordinates in the patterning field.

Example 2 includes the subject matter of Example 1, and further specifies that the directed energy beam is a charged particle beam (CPB).

Example 3 includes the subject matter of any of Examples 1-2, and further specifies that the charged particle beam (CPB) is an electron beam.

Example 4 includes the subject matter of any of Examples 1-3, and further specifies that the directed energy beam is a laser beam.

Example 5 includes the subject matter of any of Examples 1-4, and further includes: with a camera, obtaining at least one image of a reticle situated at the patterning field, the reticle defining a plurality of calibration features; processing the image of the reticle to establish a mapping of pixel coordinates of the calibration features in the image of the reticle to patterning field spatial coordinates based on locations of the calibration features in the patterning field; and establishing the compensated beam deflections for the patterning field based on the established mapping.

Example 6 includes the subject matter of any of Examples 1-5, and further includes establishing locations of a plurality of pattern features in the patterning field by translating each of the pattern features to a reference location in the patterning field and recording the translations, wherein the compensated beam deflections for the patterning field are established based on the translations of the pattern features.

Example 7 includes the subject matter of any of Examples 1-6, and further specifies that the at least one image of cathodoluminescence, plasma emission, blackbody radiation, or surface damage from the scan locations in response to the directed energy beam is obtained with a camera and the reference location is situated on an axis of the camera.

Example 8 includes the subject matter of any of Examples 1-7, and further specifies that the processing of the image of the reticle to map pixel coordinates in the at least one image of the reticle to patterning field spatial coordinates is based on predetermined locations of the plurality of calibration features on the reticle.

Example 9 includes the subject matter of any of Examples 1-8, and further specifies that the camera is situated along an axis that is tilted with respect an axis of the directed energy beam, and the at least one image of the reticle exhibits keystone distortion based on the tilt, wherein the processing of the image of the reticle to map pixel coordinates in the at least one image of the reticle to patterning field spatial coordinates includes compensating for the keystone distortion.

Example 10 includes the subject matter of any of Examples 1-9, and further includes processing a workpiece situated in the patterning field by deflecting the directed energy beam to a plurality of locations using the compensated beam deflections.

Example 11 includes the subject matter of any of Examples 1-10, and further specifies that the mapping of pixel coordinates to spatial coordinates in the patterning field comprises a database of compensated beam deflections and the deflections applied are determined by interpolation of values from the database or wherein the mapping comprises a mathematical function that is a fit to the compensated beam deflections and the deflections applied are determined by the mathematical function.

Example 12 is a method of providing compensated deflections to a directed energy beam in an additive manufacturing (AM) system, including: with the directed energy beam, defining a plurality of calibration features on a target situated at a patterning field; with a camera, obtaining an image of the plurality of calibration features; processing the image of the plurality of calibration features to map pixel coordinates of the calibration features in the image to patterning field spatial coordinates based on locations of the calibration features in the patterning field; and establishing compensated beam deflections in the AM system for the patterning field based on the mapping.

Example 13 includes the subject matter of Example 12, and further includes establishing locations of the plurality of calibration features in the patterning field by translating each of the calibration features to a reference location in the patterning field and recording the translations.

Example 14 includes the subject matter of any of Examples 11-13, and further includes measuring coordinates of the calibration features defined by the directed energy beam to establish the locations of the plurality of calibration features in the patterning field.

Example 15 is an additive manufacturing (AM) apparatus, including: a directed energy beam source; a directed energy beam deflector operable to deflect a directed energy beam from the directed energy beam source to scan locations in a patterning field; a camera situated to produce at least one image of cathodoluminescence, plasma emission, blackbody radiation, or surface damage from the scan locations in the patterning field in response to the directed energy beam; and a deflection driver coupled to the directed energy beam deflector and operable to produce compensated beam deflections based on a mapping of pixel coordinates in the at least one image of cathodoluminescence, plasma emission, blackbody radiation, or surface damage from the scan locations to spatial coordinates in the patterning field.

Example 16 includes the subject matter of Example 15, and further specifies that the directed energy beam source is a charged-particle beam (CPB) source.

Example 17 includes the subject matter of any of Examples 15-16, and further specifies that the directed energy beam source is a laser.

Example 18 includes the subject matter of any of Examples 15-17, and further specifies that a wavelength of the laser is different from a wavelength range imaged by the camera.

Example 19 includes the subject matter of any of Examples 15-18, and further specifies that the deflection driver is operable to deflect the directed energy beam to a plurality of scan locations in the pattering field to produce the at least one image of cathodoluminescence, plasma, blackbody radiation image, or surface damage image with the camera.

Example 20 includes the subject matter of any of Examples 15-19, and further specifies that the camera is situated along an axis that is tilted with respect to an axis of the directed energy beam or a perpendicular at the patterning field.

Example 21 includes the subject matter of any of Examples 15-20, and further includes a memory storing nominal beam deflections associated with the scan locations.

Example 22 includes the subject matter of any of Examples 15-21, and further specifies that the memory is operable to store nominal deflection values associated with the scan locations and associated patterning field coordinates.

Example 23 includes the subject matter of any of Examples 15-22, and further specifies that the deflection driver is operable to establish the mapping of the pixel coordinates in the at least one image to patterning field coordinates based on locations of calibration features in the patterning field.

Example 24 includes the subject matter of any of Examples 15-23, and further specifies that the deflection driver is operable to receive a part specification and produce compensated beam deflections with the directed energy beam deflector in response to the part specification.

Example 25 is a deflection control system for a directed energy beam, including: a camera situated to obtain an image of a patterning field based on cathodoluminescence, plasma emission, blackbody radiation, or surface damage from a plurality of scan locations; and a processor coupled to the camera to receive the image of the patterning field at the scan locations and determine compensated deflection values based on the images.

Example 26 includes the subject matter of Example 25, and further specifies that the processor is configured to produce the compensated deflection values based on a mapping of pixel coordinates in the image of the patterning field to spatial coordinates in the patterning field.

Example 27 includes the subject matter of any of Examples 25-26, and further specifies that the processor is further configured to obtain an image of a reticle situated at the patterning field and wherein the scan locations are determined based on the image of the reticle.

Example 28 includes the subject matter of any of Examples 25-28, and further specifies that the processor is configured to determine the scan locations based on measured locations of the surface damage.

Example 29 is a method of providing compensated deflections to a directed energy beam, including: obtaining an image of at least one calibration feature; obtaining at least one image of cathodoluminescence, plasma emission, blackbody radiation, reflected beam energy, or surface damage based on the directed energy beam; and extracting locations of the directed energy beam based on the at least one calibration feature and the image of cathodoluminescence, plasma emission, blackbody radiation, reflected beam energy, or surface damage.

Example 30 is an additive manufacturing (AM) method, including: recording a position of a patterning base with respect to an alignment pattern; generating information regarding deflections of a printing beam in a patterning field with respect to the alignment pattern; and printing at least one feature on the patterning base with the generated information regarding the deflections and the recorded position of the patterning base.

Example 31 includes the subject matter of Example 30, and further includes: mapping deflections of a printing beam in the patterning field with respect to the alignment pattern to generate the information regarding the deflections.

Example 32 includes the subject matter of any of Examples 30-31, and further specifies that the alignment pattern is an alignment fiducial associated with an image of a calibration reticle.

Example 33 includes the subject matter of any of Examples 30-32, and further includes: with a camera, obtaining an image of a calibration reticle situated in a patterning field; and processing the image of the calibration to produce the alignment fiducial.

Example 34 includes the subject matter of any of Examples 30-33, further comprises recording deflections of the printing beam with a camera based on a scan of the printing beam, wherein the mapping of the printing beam to the alignment fiducial is based on the recorded deflections of the printing beam.

Example 35 includes the subject matter of any of Examples 30-35, and further specifies that the printing beam is an electron beam, and the recorded deflections of the printing beam in the patterning field are based on a cathodoluminescence, blackbody radiation, or surface damage image produced with the camera and associated with the scan of the printing beam.

Example 36 is an additive manufacturing (AM) apparatus, including: a printing beam source; a printing beam deflector operable to deflect a printing beam from the printing beam source to scan locations in a patterning field; a camera situated to produce an image of a deflection field defined by deflecting the printing beam in the patterning field and an image associated with a patterning base with respect to an alignment pattern; and a processor coupled to determine printing beam deflections based on the image associated with the deflection field, and the image associated with the patterning base.

Example 37 includes the subject matter of Example 36, and further specifies that the camera is situated to further produce an image of a calibration reticle situated in the patterning field, and the printing beam deflections are determined by the processor based on the image of the calibration reticle, the image associated with the deflection field, and the image associated with the patterning base, and the processor is coupled to determine printing beam deflections based on the image associated with the deflection field, and the image associated with the patterning base.

Example 38 includes the subject matter of any of Examples 36-37, and further specifies that the processor is operable to establish an alignment fiducial based on the image of the calibration reticle, and the printing beam deflections are determined based on mapping of the deflection field to coordinates with respect to the alignment fiducial.

Example 39 includes the subject matter of any of Examples 36-38, and further specifies that the processor is operable to map the image associated with the patterning base to coordinates defined by the alignment fiducial.

In view of the many possible embodiments to which the principles of the disclosed technology may be applied, it should be recognized that the illustrated embodiments are only preferred examples and should not be taken as limiting the scope of the disclosure. The above-mentioned method may be used to correct changes in the patterning beam due to fluctuations in a magnetic field.

1-39. (canceled)

40-86. (canceled)

87. A method of providing compensated deflections to a directed energy beam, comprising:
directing an energy beam to a target situated in a patterning field to each of a plurality of scan locations using respective beam deflection signals;
with a camera, obtaining a first image including at least one image of cathodoluminescence, plasma emission, blackbody radiation, or surface damage from the scan locations in response to the directed energy beam; and
with a camera, obtaining at least second image including one image of calibration object situated at the patterning field, the calibration object defining a plurality of calibration features;
establishing compensated beam deflections for the patterning field based on the first image and the second image.

88. The method of claim 87, further comprising:
processing the second image to establish a mapping of pixel coordinates of the calibration features in the image of the calibration object to patterning field spatial coordinates based on locations of the calibration features in the patterning field.

89. The method of claim 87, further comprising:
establishing compensated beam deflections for the patterning field based on a mapping of pixel coordinates of the first image.

90. The method of claim 87, wherein the directed energy beam is a laser beam.

91. The method of claim 87, further comprising establishing locations of a plurality of pattern features in the patterning field by translating each of the pattern features to a reference location in the patterning field and recording the translations, wherein the compensated beam deflections for the patterning field are established based on the translations of the pattern features.

92. The method of claim 91, wherein the first image is obtained with a camera and the reference location is situated on an axis of the camera.

93. The method of claim 88, wherein the processing of the second image of the calibration object to map pixel coordinates in the second image of the calibration object to patterning field spatial coordinates is based on predetermined locations of the plurality of calibration features on the calibration object.

94. The method of claim 88, wherein the camera is situated along an axis that is tilted with respect an axis of the directed energy beam, and the second image of the calibration object exhibits keystone distortion based on the tilt, wherein the processing of the image of the calibration object to map pixel coordinates in the at least one image of the calibration object to patterning field spatial coordinates includes compensating for the keystone distortion.

95. The method of claim 88, further comprising processing a workpiece situated in the patterning field by deflecting the directed energy beam to a plurality of locations using the compensated beam deflections.

96. The method of claim 95, wherein the mapping of pixel coordinates to spatial coordinates in the patterning field comprises a database of compensated beam deflections and the compensated beam deflections applied are determined by interpolation of values from the database of compensated beam deflections or wherein the mapping comprises a mathematical function that is a fit to the compensated beam deflections and the deflections applied are determined by the mathematical function.

97. The method of claim 87, wherein the calibration object is a reticle.

98. An additive manufacturing (AM) apparatus, comprising:
a directed energy beam source;
a directed energy beam deflector operable to deflect a directed energy beam from the directed energy beam source to scan locations in a patterning field;
a camera situated to produce a first image including at least one image of cathodoluminescence, plasma emission, blackbody radiation, or surface damage from the scan locations in the patterning field in response to the directed energy beam; and
a deflection driver coupled to the directed energy beam deflector and operable to produce compensated beam deflections based on the first image.

99. The AM apparatus of claim 98, further comprising a deflection driver coupled to the directed energy beam deflector and operable to produce compensated beam deflections based on a mapping of pixel coordinates in the first image.

100. The AM apparatus of claim 98, wherein the directed energy beam source is a laser.

101. The AM apparatus of claim 100, wherein a wavelength of the laser is different from a wavelength range imaged by the camera.

102. The AM apparatus of claim 98, wherein the deflection driver is operable to deflect the directed energy beam to a plurality of scan locations in the pattering field to produce the first image.

103. The AM apparatus of claim 98, wherein the camera is situated along an axis that is tilted with respect to an axis of the directed energy beam or a perpendicular at the patterning field.

104. The AM apparatus of claim 98, further comprising a memory storing nominal beam deflections associated with the scan locations.

105. The AM apparatus of claim 104, wherein the memory is operable to store nominal deflection values associated with the scan locations and associated patterning field coordinates.

106. The AM apparatus of claim 105, wherein the deflection driver is operable to establish the mapping of the pixel coordinates in the first image to patterning field coordinates based on locations of calibration features in the patterning field.

107. The AM apparatus of claim 105, wherein the deflection driver is operable to receive a part specification and produce compensated beam deflections with the directed energy beam deflector in response to the part specification.

108. A deflection control system for a directed energy beam, comprising:
a camera situated to obtain a first image of a patterning field based on cathodoluminescence, plasma emission, blackbody radiation, or surface damage from a plurality of scan locations; and
a processor coupled to the camera to receive the first image of the patterning field at the scan locations and determine compensated deflection values based on the first image.

109. The deflection control system of claim 108, wherein the processor is configured to produce the compensated deflection values based on a mapping of pixel coordinates in the image of the patterning field to spatial coordinates in the patterning field.

110. The deflection control system of claim 108, wherein the processor is further configured to obtain an image of a calibration object situated at the patterning field and wherein the scan locations are determined based on the image of the calibration object.

111. The deflection control system of claim 110, wherein the processor is configured to determine the scan locations based on measured locations of the surface damage.

112. The deflection control system of claim 108, wherein the calibration object is a reticle.
